(19) United States
(12) Patent Application Publication
(10) Pub. No.: US 2012/0236307 A1
(43) Pub. Date: Sep. 20, 2012

(54) PHOTOCONDUCTIVE ELEMENT

(75) Inventor: Ryota Sekiguchi, Kawasaki-shi (JP)

(73) Assignee: CANON KABUSHIKI KAISHA, Tokyo (JP)

(21) Appl. No.: 13/416,421

(22) Filed: Mar. 9, 2012

(30) Foreign Application Priority Data
Mar. 18, 2011 (JP) 2011-061440

(51) Int. Cl. G01J 3/28; H01L 31/0352; H01L 33/06

(52) U.S. Cl. 356/402; 257/13; 257/21; 257/E33.008; 257/E31.033

(57) ABSTRACT

There is provided a photoconductive element capable of increasing an output and detection sensitivity by increasing resistivity as the entire element. The photoconductive element is a photoconductive element capable of generating or detecting an electromagnetic wave when light is emitted thereto. The photoconductive element includes a photoconductive layer having a semiconductor layer whose resistivity changes when light is emitted to thereby generate or detect an electromagnetic wave; and a plurality of electrodes provided in contact with the semiconductor layer. The resistivity of the semiconductor layer changes in a thickness direction of intersecting a surface of the semiconductor layer contacting the electrodes. Assuming that the semiconductor layer includes a first region and a second region which is farther away from the electrodes in the thickness direction than the first region, the resistivity in the first region is greater than the resistivity in the second region.

### BACKGROUND OF THE INVENTION

1. Field of the Invention

The present invention relates to a photoconductive element and an electromagnetic wave generating/detecting apparatus for generating or detecting an electromagnetic wave by irradiation of excitation light (note that “generating/detecting” and “generating or detecting” means being capable of at least one of generating and detecting).

2. Description of the Related Art

The electromagnetic wave (also referred to simply as a terahertz wave in the present specification) including a component in a frequency band from a millimeter-wave band to a terahertz-wave band (30 GHz or more and 30 THz or less) has the following characteristics. First, the wave transmits a non-metallic substance like X-ray. Second, the wave includes many absorption spectra specific to biological molecules and pharmaceutical products. Third, the wave has a spatial resolution required for many imaging applications. From the above characteristics, a spectroscopy technique inside a substance, a safe fluoroscopic imaging system as an alternative to an X-ray system, and an analysis technique for biological molecules and pharmaceutical products have been developed as application fields of terahertz wave.

A terahertz wave can be generating and detecting using various methods, and among them, a method using a photoconductive element (disclosed in Japanese Patent Application Laid-Open No. 2006-086227) is widely used. The photoconductive element includes a special semiconductor having a relatively high mobility and having a carrier lifetime of a picosecond or less; and two electrodes disposed thereon. When light irradiation is performed on a gap between the electrodes in a state in which a voltage is applied between the electrodes, a picosecond-order current flows between the electrodes, whereby a terahertz wave is emitted. On the contrary, when light irradiation is performed on a gap between the electrodes in a state in which a voltage is not applied between the electrodes, an instantaneous electric field induced by terahertz wave is sampled and detected as a current. In order to increase the output and the detection sensitivity of the terahertz wave, the aforementioned special semiconductor (also referred to as a photoconductive film) preferably has a higher resistivity. A photoconductive element for solving this is disclosed in Japanese Patent Application Laid-Open No. 2006-086227. The photoconductive element illustrated in FIG. 7 includes an InP substrate 11, an InGaAs photoconductive film 12, and electrodes 13 and 14. The InGaAs 12 is a photoconductive film having Fe ions injected therein and having an increased resistivity. A voltage is applied to the photoconductive film 12 from a power supply 2. When the photoconductive film 12 is irradiated with a short pulse light 3 (with a wavelength of about 1.5 μm) with a pulse width of a femtosecond from an unillustrated laser apparatus, a terahertz wave 4 is emitted from an antenna also serving as electrodes 13 and 14.

### SUMMARY OF THE INVENTION

Unfortunately, the conventional photoconductive element has a limit to increase the resistivity of the photoconductive layer. The limit is substantially determined by a band gap of the semiconductor material to be used. That is, the smaller the band gap is, the more the thermally excited carrier increases, whereby it is difficult to increase the resistivity. Therefore, there is a limit depending on the material to increase the output of the photoconductive element and the detection sensitivity corresponding to a wavelength region (wavelength region corresponding to a relatively small band gap) of a fiber laser such as a 1.0 μm band and a 1.5 μm band.

In view of the above problems, the photoconductive element of the present invention is a photoconductive element that can generate or detect an electromagnetic wave when light is emitted thereto. The photoconductive element includes a photoconductive layer having a semiconductor layer whose resistivity changes when light is emitted to thereby generate or detect an electromagnetic wave; and a plurality of electrodes provided in contact with the semiconductor layer. The resistivity (resistance per unit volume) of the semiconductor layer changes in a direction of intersecting a surface of the semiconductor layer contacting the electrodes. Assuming that the semiconductor layer includes a first region and a second region which is farther away from the electrodes in the intersecting direction than the first region, the resistivity in the first region is greater than the resistivity in the second region.

According to the present invention, the resistivity of the semiconductor layer forming the photoconductive layer changes in a direction (in a thickness direction, and generally in a vertical direction) of intersecting a surface of the semiconductor layer contacting a plurality of electrodes. Further, assuming that the semiconductor layer forming the photoconductive layer includes a first thickness region and a second thickness region which is farther away from the electrodes than the first thickness region, the resistivity in the first thickness region is greater than the resistivity in the second thickness region. Accordingly, the current from the electrodes is not concentrated in the first thickness region, whereby the sensitivity of the entire element is increased. Thus, a photoconductive element increasing the output and detection sensitivity can be provided. Further, it is easy to provide a configuration in which the light absorption wavelength in the first thickness region is shorter than the light absorption wavelength in the second thickness region. Thus, the photoconductive element can effectively absorb excitation light and it can increase the output and the detection sensitivity.

Further features of the present invention will become apparent from the following description of exemplary embodiments with reference to the attached drawings.

### BRIEF DESCRIPTION OF THE DRAWINGS

FIG. 1 is a sectional view illustrating a configuration of a photoconductive element according to a first embodiment.

FIGS. 2A, 2B and 2C are diagrams illustrating a correspondence between an element configuration and an equivalent circuit element of the first embodiment.

FIG. 3 is a sectional view illustrating a configuration of a photoconductive element according to a second embodiment.

FIGS. 4A and 4B are diagrams illustrating a configuration of an electromagnetic wave generating/detecting apparatus and a photoconductive element according to a first example.

FIGS. 5A and 5B are diagrams illustrating a configuration of an electromagnetic wave generating/detecting apparatus and a photoconductive element according to a second example.

FIG. 6 is a schematic view of a terahertz time-domain spectroscopy system using the electromagnetic wave generating/detecting apparatus.

FIG. 7 is a perspective view illustrating a configuration of a conventional photoconductive element.

### DESCRIPTION OF THE EMBODIMENTS

Preferred embodiments of the present invention will now be described in detail in accordance with the accompanying drawings.

What matters in the photoconductive element of the present invention is that the resistivity of the semiconductor layer forming the photoconductive layer satisfies the following conditions. First, the resistivity changes in a direction of intersecting a surface of the semiconductor layer contacting a plurality of electrodes. Further, assuming that the semiconductor layer arbitrarily includes a first region and a second region which is farther away from the electrodes in the intersecting direction than the first region, the resistivity in the first region is greater than the resistivity in the second region. The regions have a thickness in a macroscopic scale (for example, about 100 nm or more in the semiconductor) in the intersecting direction and the resistivity refers to an average resistivity thereof.

In a typical embodiment, two or more semiconductor layers having a different resistivity and absorption wavelength are used to arrange electrodes so as to effectively increase an element resistance as the entire element. More specifically, a semiconductor layer with a high resistivity is arranged in the first thickness region close to the electrodes, and a semiconductor layer with a lower resistivity is arranged in the second thickness region far away from the electrodes. Further, a wavelength component of excitation light is divided so as to satisfy this relationship also during light absorption. A semiconductor layer for absorbing light with a short-wavelength component of the excitation light is arranged in the first thickness region and a semiconductor layer for absorbing light with a long-wavelength component having a wavelength longer than the short-wavelength component is arranged in the second thickness region in this order. Such an arrangement in this order from the light incident side allows the excitation light to be effectively absorbed.

A photoconductive layer has a function that when the photoconductive layer is irradiated with pump light or probe light, the resistivity of the photoconductive layer changes and, based on the optical switching at this time, the photoconductive layer generates and detects an electromagnetic wave. It follows that the resistivity of the semiconductor layer itself forming the photoconductive layer also changes.

Hereinafter, embodiments or examples of the present invention will be described with reference to the accompanying drawings.

### First Embodiment

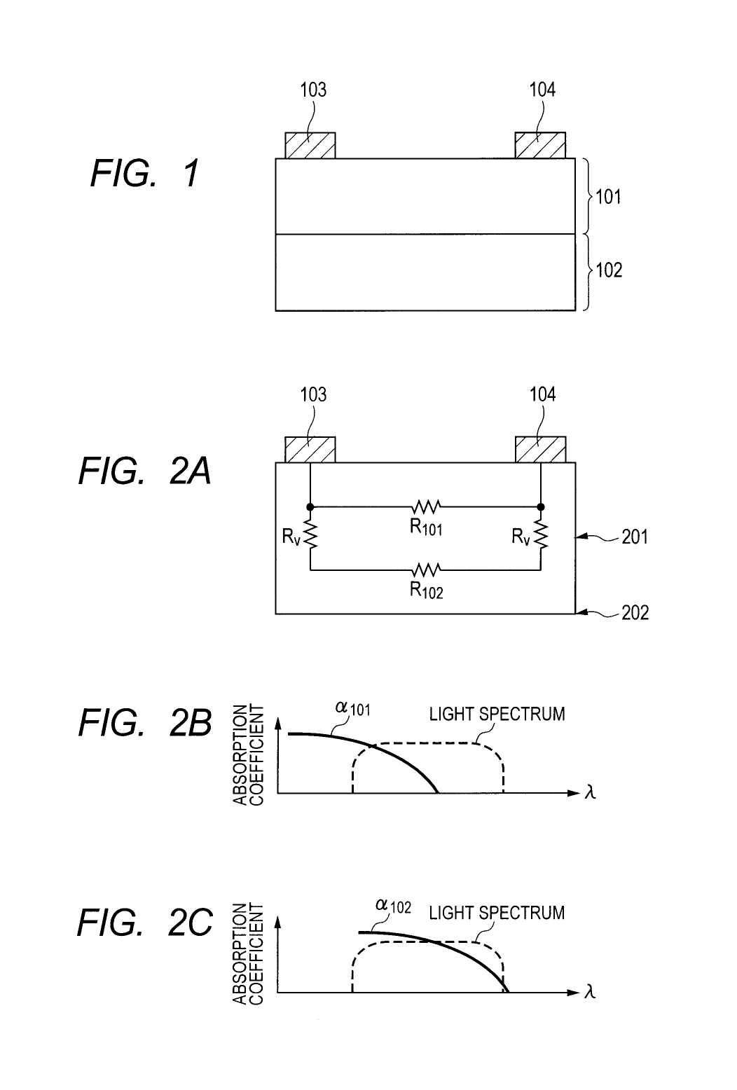

With reference to FIGS. 1, 2A, 2B and 2C, the photoconductive element according to the first embodiment will be described. FIG. 1 is a sectional view of the photoconductive element according to present embodiment. FIGS. 2A, 2B and 2C are diagrams illustrating a correspondence between an element configuration and an equivalent circuit element.

The photoconductive element of the present embodiment includes a semiconductor layer 101 forming a photoconductive film, a semiconductor layer 102 stacked thereunder, and two electrodes 103 and 104 contacting the semiconductor layer 101. The semiconductor layer 101 is made of a semiconductor with a relatively high resistivity and for example, it has a relatively large band gap. In comparison with the semiconductor layer 101, the semiconductor layer 102 is made of a semiconductor with a relatively low resistivity and for example, it has a relatively small band gap. An equivalent circuit of the above structure when viewed from the surface of the semiconductor layers with the two electrodes 103 and 104 contacting thereto can be expressed as illustrated in FIG. 2A. More specifically, R101 (resistor of the semiconductor layer 101) refers to a resistor for integrating the resistivity from the electrodes to the first thickness 201; and R102 (resistor of the semiconductor layer 102) refers to a resistor for integrating the resistivity from the first thickness 201 to the second thickness 202. Further, Rv refers to a resistor in a vertical direction proportional to the distance from the electrodes 103 and 104. Since a value of the resistor R101 is greater than a value of the resistor R102, a current between the two electrodes 103 and 104 is not concentrated in the resistor R101, but it also flows in the resistor R102. The allocation is determined by a ratio between the value of the R101 and the value (R102+2Rv) including the resistor Rv in the vertical direction. Preferably the contact area between the electrodes 103 and 104 and the semiconductor layer 101 is designed to be small to increase the value of the resistor Rv such that the value of the R101 and the value of (R102+2Rv) are in the same order of magnitude. Such a configuration (R101=R102+2Rv) is expected to exert a prominent effect of generating and detecting an electromagnetic wave by means of two layers through which substantially the same current flows. In any case, the element resistance of the present embodiment is higher than that in which the semiconductor layer 101 is made of the same material as that of the semiconductor layer 102 (a typical configuration of a conventional photoconductive element with the same thickness).

In the above configuration of the present embodiment, the resistivity of the semiconductor layers 101 and 102 changes in a direction of intersecting the surface of the semiconductor layer contacting the electrodes. Further, assuming that the semiconductor layer arbitrarily includes a first region (for example, the semiconductor layer 101) and a second region (for example, the semiconductor layer 102) which is farther away from the electrodes in the width direction than the first region, the semiconductor layer is formed such that the resistivity in the first region 101 is greater than the resistivity in the second region 102.

The photoconductive element of the present embodiment is an element for generating or detecting an electromagnetic wave pulse which is generally excited by use of a short pulse light. The spectrum of the excitation light excited by the short pulse light includes a wide range of wavelength components. The relation between an excitation light spectrum and an absorption spectrum of the semiconductor layers 101 (wavelength dependence of absorption coefficients α101) is illustrated in FIG. 2B and the relation between an excitation light spectrum and an absorption spectrum of the semiconductor layers 102 (wavelength dependence of absorption coefficients α102) is illustrated in FIG. 2C. The semiconductor layer 101 with a large band gap mainly absorbs short-wavelength components; and the semiconductor layer 102 with a small band gap mainly absorbs long-wavelength components. In other word, the light absorption wavelength of the semiconductor layer 101 is shorter than the light absorption wavelength of the semiconductor layer 102. Accordingly, the number of optical carriers is evenly distributed between the semiconductor layers 101 and 102, whereby the element resistance is also increased at light absorption. The excitation light is preferably incident from the side of the two electrodes 103 and 104. In this configuration, the excitation light propagates through the semiconductor layer 101 and the semiconductor layer 102 in this order. The semiconductor layer 101 can transmit through the long-wavelength component of the excitation light spectrum and absorb only the short-wavelength component thereof. The semiconductor layer 102 can absorb the transmitted long-wavelength component. Thus, the semiconductor layers can effectively absorb light. Apparently, as is well known to those skilled in the art, the semiconductor layers 101 and 102 may be implemented by a semiconductor layer subjected to low-temperature growth so as to form a photoconductive film with a relatively large mobility and a carrier lifetime of a picosecond or less.

In the present embodiment, the photoconductive film is implemented by two semiconductor layers, but apparently without being limited to this, it may be implemented by three semiconductor layers and generally it may be implemented by a plurality of semiconductor layers. The characteristics (referring to the resistivity and the band gap in the present embodiment) in the thickness direction of the photoconductive film are not limited to a steppedly distributed configuration, and it may be a gradedly distributed configuration. As a means for this purpose, the semiconductor layers 101 and 102 may have a different composition like the present embodiment, or the semiconductor layers 101 and 102 may have a different doping concentration (i.e., have a different carrier concentration). Alternatively, the semiconductor layers 101 and 102 may have a different growth temperature. For example, there has been known a tendency that, in a temperature range of between 100° C. and 500° C., when the growth temperature (or the anneal temperature after growth) is low, the resistivity is lowered. Thus, in this case, the semiconductor layer 101 may have a growth temperature of 500° C. and the semiconductor layer 102 may have a growth temperature of 200° C. Note that although in the present embodiment and the following example the characteristics in a lateral direction of each region in the thickness direction of the semiconductor layer are uniformly formed, the present embodiment is not limited to such configuration. The resistivity of the semiconductor layer may change in a direction of intersecting a line of electric force when a voltage is applied between the two electrodes. In this case, the characteristics in the lateral direction of the semiconductor layer become uneven. Specifically, there can be considered a configuration in which a portion between the electrodes has the highest resistivity, and the resistivity changes from this portion to the lateral direction.

### Second Embodiment

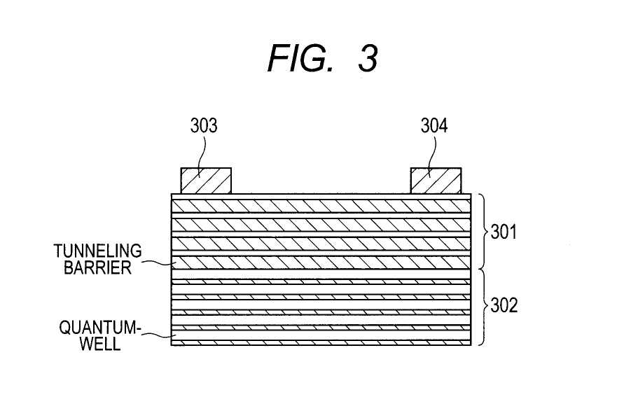

With reference to FIG. 3, the photoconductive element according to the second embodiment will be described. FIG. 3 is a sectional view of the photoconductive element, which is a variation of the first embodiment, according to the present embodiment. The present embodiment is different from the first embodiment in the configuration of a photoconductive film. Semiconductor superlattices 301 and 302 are used in the present embodiment. Note that electrodes 303 and 304 are the same as those in the first embodiment.

A semiconductor superlattice structure has been known as an artificial material obtained by repeating a pair of a quantum well with a thickness of about several nm and a tunneling barrier, and it can control an effective band gap of carriers and a macroscopic resistivity in a lateral direction. The effective band gap can be evaluated by the energy difference from the bottom of an electron miniband in the conduction band to the top of a hole miniband in the valence band. In general, when a thin quantum well or a thick tunneling barrier is used, the effective band gap is increased. For details, the Kronig-Penney model for the semiconductor superlattice structure as is well known by those skilled in the art can be referred. Regarding the resistivity in the lateral direction of the semiconductor superlattice, the probability density of carriers in the tunneling barrier is low, and thus, when a thick tunneling barrier is used, the macroscopic resistivity increases. Consequently, in the present embodiment, the semiconductor layer 301 is made of a semiconductor superlattice layer having a thin quantum well and a thick tunneling barrier; and the semiconductor layer 302 is made of a semiconductor superlattice layer having a thicker quantum well and a thinner tunneling barrier.

The semiconductor superlattice structure of the present embodiment may be implemented by a generally well-known semiconductor heterojunction such as GaAs/AlGaAs and InGaAs/InAlAs. Note that the semiconductor superlattice layers 301 and 302 may be implemented by a semiconductor superlattice layer subjected to low-temperature growth so as to form a photoconductive film with a relatively large mobility and a carrier lifetime of a picosecond or less. In the present embodiment, the photoconductive film is implemented by two semiconductor superlattice structures, but obviously without being limited to this, the photoconductive film may be implemented by three semiconductor superlattice structures and generally may be implemented by a plurality of semiconductor superlattice structures. Further, the structure (referring to at least one of: the thickness and the depth of the quantum well; and the thickness and the height of the tunneling barrier, in the present embodiment) in the width direction of the photoconductive film is not limited to a steppedly distributed configuration, and it may be a gradedly distributed configuration.

A further specific photoconductive element will be described with reference to the following examples.

### FIRST EXAMPLE

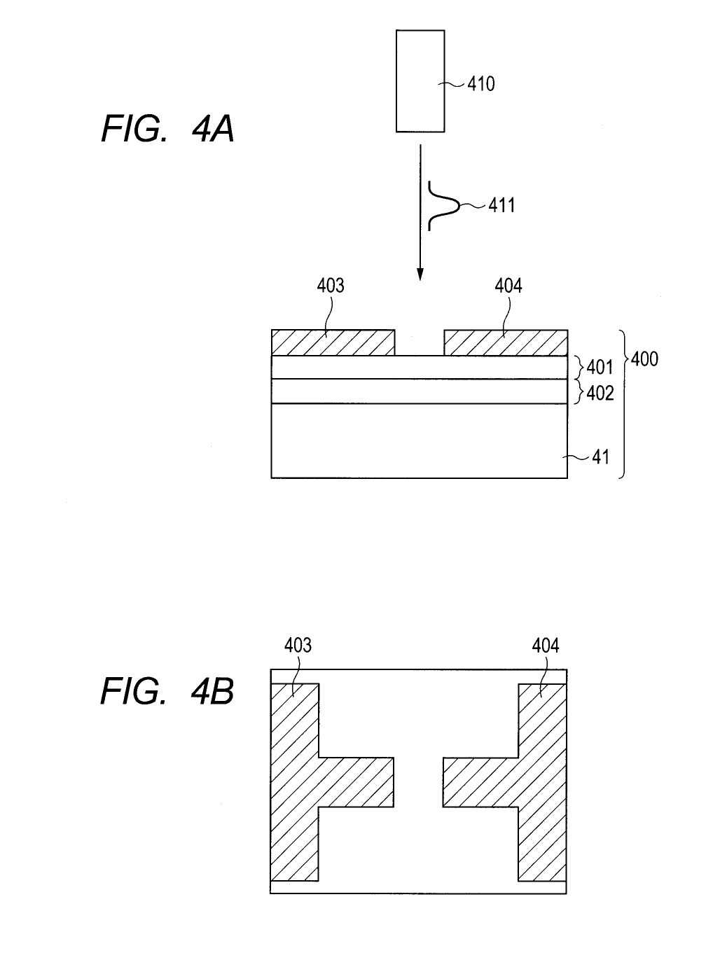

With reference to FIGS. 4A and 4B, a specific electromagnetic wave generating/detecting apparatus according to the first example will be described. FIG. 4A is a sectional view illustrating a configuration of the electromagnetic wave generating/detecting apparatus and the photoconductive element according to the present example. FIG. 4B is a top view illustrating a configuration of the photoconductive element.

In the present example, the photoconductive film includes an LT-InGaAsP layer 401 and an LT-InGaAs layer 402. These layers are formed by crystal growth on a semi-insulating InP substrate 41. The prefix “LT-” refers to a low-temperature growth method for use in the crystal growth. For example, an molecular beam epitaxy (MBE) method is used to perform crystal growth at a temperature of about 250° C. The LT-InGaAsP layer 401 has a band gap corresponding to 1.5 μm; and the LT-InGaAs layer 402 has a band gap corresponding to 1.67 μm. In the present example, each thickness of the layers is 1 μm. The electrodes 403 and 404 formed on the semiconductor layer 401 serve as an antenna. In the present example, the electrodes 403 and 404 have a shape of a dipole antenna. As the antenna shape, a dipole antenna and a bowtie antenna are well-known. Since the antenna is attached to the substrate 41, The radiating pattern of a terahertz wave has a shape that it is large on a high permittivity side, namely, on the side of the substrate 41.

The photoconductive element 400 of the present example is excited by a 1.5 μm-band fiber laser apparatus 410 for generating a short pulse light 411 with a pulse width of several ten femtoseconds. The excitation light 411 is emitted to a gap portion between the antennas 403 and 404 and sequentially propagates through the semiconductor layers 401 and 402. The LT-InGaAsP layer 401 absorbs a band near 1.5 μm thereof and the LT-InGaAs layer 402 absorbs a band near 1.67 μm thereof to generate or detect the terahertz wave. For generation, a voltage may be applied to both electrodes 403 and 404 by an unillustrated power supply. When the excitation light 411 is absorbed, a carrier having a lifetime of about a picosecond is generated and accelerated. Carrier acceleration generates an electromagnetic field. For detection, an unillustrated ammeter is connected to both electrodes 403 and 404. When the excitation light 411 is irradiated at the same time when the terahertz wave electric field to be detected is generated, the terahertz electric field (substantially a DC electric field) sampled by an optical carrier due to the excitation light generates a current. The terahertz wave is detected by detecting the current.

### SECOND EXAMPLE

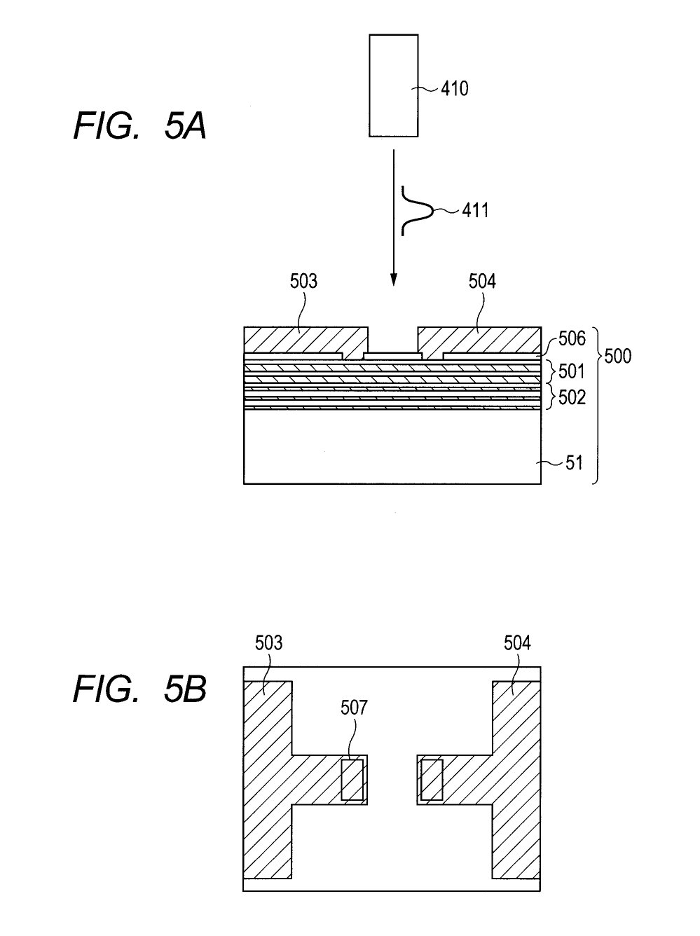

With reference to FIGS. 5A and 5B, a specific example of the electromagnetic wave generating/detecting apparatus according to the second example will be described. FIG. 5A is a sectional view illustrating a configuration of the electromagnetic wave generating/detecting apparatus and the photoconductive element according to the present example. FIG. 5B is a top view illustrating a configuration of the photoconductive element.

The photoconductive film according to the present example includes LT-InGaAs/InAlAs semiconductor superlattice layers 501 and 502. These layers are formed by crystal growth on a semi-insulating InP substrate 51. The semiconductor superlattice layer 501 is formed by repeating 50 cycles of the 6-nm quantum well/9-nm tunneling barrier; and the semiconductor superlattice layer 502 is formed by repeating 50 cycles of the 12-nm quantum well/8-nm tunneling barrier. Thus, a photoconductive film is formed such that the macroscopic resistivity of the semiconductor superlattice layer 501 (corresponding to R101) is greater than the macroscopic resistivity of the semiconductor superlattice layer 502 (corresponding to R102). The semiconductor superlattice layers 501 and 502 absorb the short-wavelength side of the excitation light spectrum and the long-wavelength side thereof longer by about 0.2 eV, respectively. The LT-InGaAs may be doped with beryllium (Be) as an impurity. Since Be can be used for a dopant of the LT-InGaAs to compensate for an n-type carrier, an appropriate control of the doping concentration (generally, 10¹⁵ to 10¹⁸ cm⁻³) can increase the resistivity of the LT-InGaAs itself.

In the present example, the electrodes 503 and 504 contact the semiconductor layer 501 only through the portion of a contact hole 507 opened in an insulating film 506 interposed therebetween. The diameter or the side length of the contact hole may preferably satisfy about 2t²/d as a function of d and t, in which d denotes the distance of the gap portion between the antennas 503 and 504 and t denotes the thickness of the semiconductor film 502. According to the photoconductive element of the present example, the gap portion has a distance of 5 μm, and the contact hole has a diameter of 1 μm. Thus, the value of the resistor Rv can be designed to be increased such that the value of the R101 and the value of (R102+2Rv) are in the same order of magnitude.

The photoconductive element 500 of the present example is excited by a 1.5 mm-band fiber laser apparatus 410 for generating a short pulse light 411 like the first example. The method of generating and detecting the terahertz wave is the same as that in the first example.

### THIRD EXAMPLE

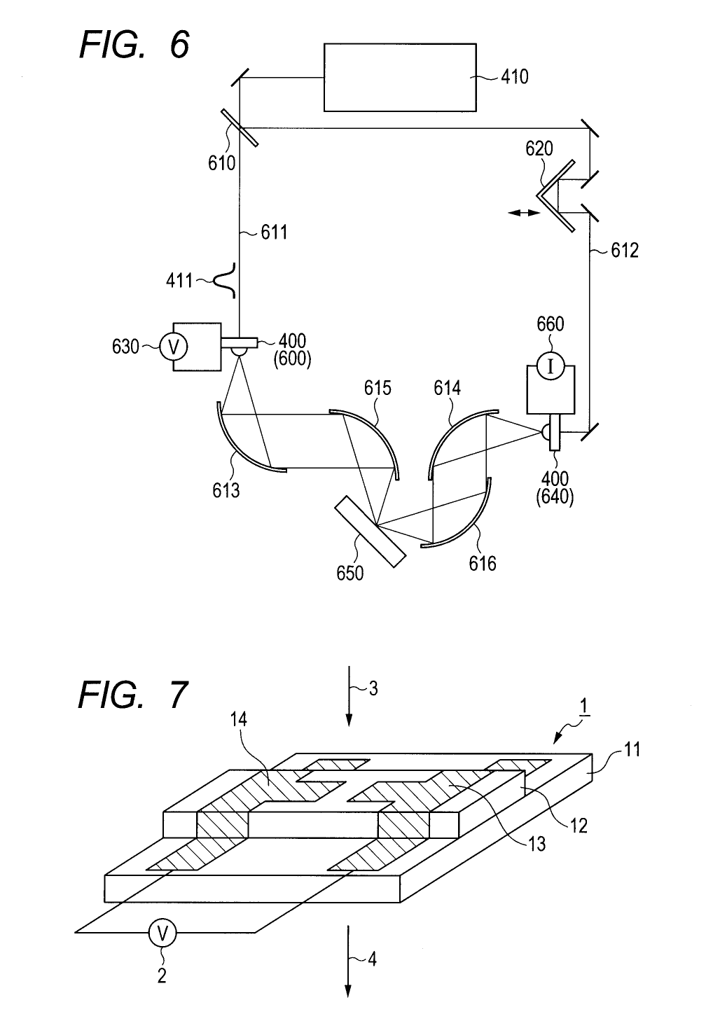

FIG. 6 illustrates a terahertz time-domain spectroscopy system (THz-TDS) using an electromagnetic wave generating apparatus according to the third example. This type of spectroscopy system itself is basically the same as a conventionally known system. This spectroscopy system includes: a short pulse laser 410 forming a light irradiation unit for emitting excitation light; half mirror 610; an optical delay system 620; a photoconductive element (electromagnetic wave generating element) 600; and a photoconductive element (electromagnetic wave detecting element) 640. The electromagnetic wave generating/detecting elements 600 and 640 of the present example can be implemented by the photoconductive element 400 corresponding to a 1.5-μm band of the first example. Pump light 611 (ultrashort pulse light 411) and probe light 612 are emitted to an electromagnetic wave generating element 600 and an electromagnetic wave detecting element 640 respectively. A terahertz wave generated by the electromagnetic wave generating element 600 to which a voltage is applied by a voltage source 630 is guided to an object 650 along terahertz guides 613 and 615. The terahertz wave including information about an absorption spectrum of the object 650 is guided along terahertz guides 616 and 614 and it is detected by the electromagnetic wave detecting element 640. At this time, the value of a current detected by an ammeter 660 is proportional to the amplitude of the terahertz wave. In order to perform time resolution (that is, to acquire the time waveform of an electromagnetic wave), the irradiation timing of the pump light and the probe light is controlled such as by moving the optical delay system 620 for changing the optical path length on the side of the probe light 612. More specifically, an adjustment is made on a delay time between the time when an electromagnetic wave is generated by the electromagnetic wave generating element 600 and the time when the electromagnetic wave is detected by the electromagnetic wave detecting element 660. As described above, the time domain spectroscopy apparatus of the present example includes at least an electromagnetic wave generating apparatus having an electromagnetic wave generating element; an electromagnetic wave detecting apparatus having an electromagnetic wave detecting element; and an adjustment unit for adjusting a delay time between the time when an electromagnetic wave is generated by the electromagnetic wave generating apparatus and the time when the electromagnetic wave is detected by the electromagnetic wave detecting apparatus. The adjustment unit is used to adjust the delay time to thereby acquire the time waveform of the generated electromagnetic wave by a sampling principle. The present configuration allows at least one of the electromagnetic wave generating apparatus and the electromagnetic wave detecting apparatus to be configured by use of the electromagnetic wave generating/detecting apparatus of the present invention.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-061440, filed Mar. 18, 2011, which is hereby incorporated by reference herein in its entirety.

What is claimed is:

1. A photoconductive element capable of generating or detecting an electromagnetic wave when light is emitted thereto, the photoconductive element comprising:
a photoconductive layer having a semiconductor layer whose resistivity changes when light is emitted to thereby generate or detect an electromagnetic wave; and
a plurality of electrodes provided in contact with the semiconductor layer, wherein
the resistivity of the semiconductor layer changes in a direction of intersecting a surface of the semiconductor layer contacting the electrodes, and
assuming that the semiconductor layer includes a first region and a second region which is farther away from the electrodes in the intersecting direction than the first region, the resistivity in the first region is greater than the resistivity in the second region.

2. The photoconductive element according to claim 1, wherein a light absorption wavelength in the first region is shorter than a light absorption wavelength in the second region.

3. The photoconductive element according to claim 1, wherein the first region and the second region are arranged in this order from the light incident side.

4. The photoconductive element according to claim 1, wherein at least one of a composition of a material forming the semiconductor layer, a carrier concentration, and a growth temperature is steppedly or gradedly distributed.

5. The photoconductive element according to claim 1, wherein the semiconductor layer has a semiconductor superlattice structure and at least one of: the thickness and the depth of a quantum well of the semiconductor superlattice structure; and the thickness and the height of a tunneling barrier thereof, is steppedly or gradedly distributed.

6. The photoconductive element according to claim 1, wherein the electrodes contact the semiconductor layer only through a portion of a contact hole opened in an insulating film interposed therebetween.

7. An electromagnetic wave generating/detecting apparatus comprising at least the photoconductive element according to claim 1; and a light irradiation unit for emitting light for exciting the photoconductive element.

8. A time domain spectroscopy apparatus comprising at least an electromagnetic wave generating apparatus; an electromagnetic wave detecting apparatus; and an adjustment unit for adjusting a delay time between the time when an electromagnetic wave is generated by the electromagnetic wave generating apparatus and the time when the electromagnetic wave is detected by the electromagnetic wave detecting apparatus, in which the adjustment unit is used to adjust the delay time to thereby sample and acquire the time waveform of the generated electromagnetic wave, and wherein
at least one of the electromagnetic wave generating apparatus and the electromagnetic wave detecting apparatus is configured by use of the electromagnetic wave generating/detecting apparatus according to claim 7.
